(19) United States
(12) Patent Application Publication
(10) Pub. No.: US 2004/0020529 A1
(43) Pub. Date: Feb. 5, 2004

(54) Device for testing solar cells

(76) Inventors: Carla Schutt, Kronberg (DE); Klaus Erfurth, Begur (ES); Christian Bendel, Schauenburg (DE)

Correspondence Address: Felix J. D'Ambrosio, Jones Tullar & Cooper P C, PO Box 2266 Eads Station, Arlington, VA, 22202, US

(21) Appl. No.: 10/399,035

(22) PCT Filed: Oct. 15, 2001
(86) PCT No.: PCT/EP01/11894

(30) Foreign Application Priority Data
Oct. 17, 2000 (DE) 100 51 357.3
Jul. 20, 2001 (EP) 01117506.4

(51) Int. Cl. H02N 6/00; H01L 25/00

(52) U.S. Cl. 136/245

(57) ABSTRACT

An apparatus (1) for the irradiation of solar cells (2) is described. The apparatus (1) contains at least 400 solid-state radiation sources in a matrix-like extensive arrangement for emitting monochromatic light in a spectral region of 880 nm, preferably for silicon cells.

The invention relates to an apparatus of the generic type stated in the precharacterizing clause of claim 1.

Known apparatuses of this type consist as a rule of a cohesive modular unit, also referred to as light simulators, contain at least one lamp, a controllable energy supply unit, a cooling unit, an optical filter unit and a detector unit for light intensity monitoring or the like. The lamps are filled with metal halide vapour or xenon gas or mixtures thereof and are used as continuous light emitters. Often, a plurality of lamps in combination with additional filters are also used. These modular units are also referred to as continuous light simulators (U.S. Pat. No. 7,394,993, JP 57179674, U.S. Pat. No. 5,217,285). Such apparatuses are used, for example, for solar cell measurements in development laboratories or in quality assurance in production plants.

Other apparatuses which use single or multiple xenon flash tubes are furthermore known, the flash time energies being adjustable. These apparatuses generally referred to as flashers or pulsed light simulators (JP 11317535, U.S. Pat. No. 3,950,862, JP 314840) are used for the measurement of solar cells during the production process.

In spite of a compact design, the apparatuses described or mentioned require a large space and have a high energy demand owing to the gas discharge lamps used or owing to the provision of brief high pulse energies.

For use in the quasicontinuous production process of solar cells, the continuous light or pulsed light simulators operated with high radiant energy have an average operating time of 750 and 9 hours, respectively, with, for example, a 3 second cycle, provided that the spectral range of the emitted radiation is still in the required range.

It is therefore the object of the invention to design the apparatus of the generic type designated at the outset in such a way that it is suitable in particular for use in quality monitoring in solar cell manufacture, can be produced in a constructionally simple manner and is compact and energy-saving.

This object is achieved, according to the invention, if the light source is a matrix of solid-state light sources with substantially monochromatic radiation in the preferred spectral sensitivity range of the solar cells to be measured and the means for actuating the light source has a current regulator.

The apparatus according to the invention has the advantage that the generally individual radiation sources used in light simulators and based on gas discharge of high intensity are replaced by a large number of physically identical solid-state radiation sources with low intensity but higher efficiency. This makes it possible for the space and energy requirement to be considerably reduced, and the life increases to a significantly high degree. In the production monitoring or function testing of solar cells, it has been found that the desired simulation of the solar spectrum is not absolutely essential. Such a test can be produced using a limited spectrum provided by solid-state radiation sources. In addition, the solid-state light sources do not change their spectral distribution on variation of the power (e.g. dimming).

For the testing of Si solar cells, the apparatus advantageously has solid-state light sources which emit radiation in the region of 880 nm. The matrix light source is advantageously designed for outputting a specific radiant power of 1200 W/m² at 25° C. These conditions are used as a basis in the currently employed apparatuses for the testing of solar cells, so that this market segment can be covered with the present invention. The above-mentioned spectral sensitivity of the solid-state light sources used is considered, by virtue of their design, to be optimum only for silicon cells. In the testing of thin-film or thin-layer cells or other photovoltaically used compound semiconductors, other light spectra may be required. Accordingly, solid-state light sources having other specific spectral light sensitivities are used for solar cells from other technologies known today.

In addition, CdTe solar cells having radiation in the region of 700 nm or CIS solar cells having radiation in the region of 600 nm with output of a specific radiant power of the matrix light source of 1200 W/m² at 25° C. can also be tested using the apparatus. Testing of other types of solar cells is likewise possible.

In an advantageous embodiment, the matrix light source has at least 400 solid-state light sources for the testing of 10×10 cm solar cells. With the aid of this number of solid-state light sources, the required power for the testing of solar cells is provided.

In a preferred embodiment, the solid-state light sources are LEDs having lenticular radiation orifices, and their matrix-like arrangement forms an approximately homogeneous radiation area at a distance of 4.3 mm±10%. The advantage here is the uniform illuminated area with which a uniform light field is produced.

Advantageously, the means for controlling the output light power of the light source is integrated in a computer-controlled evaluation unit. In an advantageous embodiment, the means for controlling the output light power comprises a computer-controlled current source with a reference light source feedback network. This compensates ageing phenomena and/or temperature deviations of the matrix light source.

In a preferred embodiment, the matrix light source is modular and can be extended by additional modules.

Advantageously, the matrix light source is in the form of an XY matrix, and the currents of the solid-state light sources are individually controllable. For producing a desired spectral distribution, the matrix light source can be composed of groups of solid-state light sources of different spectral light emission, it being possible to produce a desired mixed spectrum by suitable actuation of the groups. The use of LEDs having different spectral sensitivity permits the combination of a mixed light production which, with appropriate effort, entirely also permits the generation of an AM 1.5 spectrum, although this has not proved necessary for pure testing purposes.

It is also possible to replace the square matrix light source by rectangular or curvilinear forms, in particular circles.

The invention is illustrated below by embodiments in conjunction with the attached drawings.

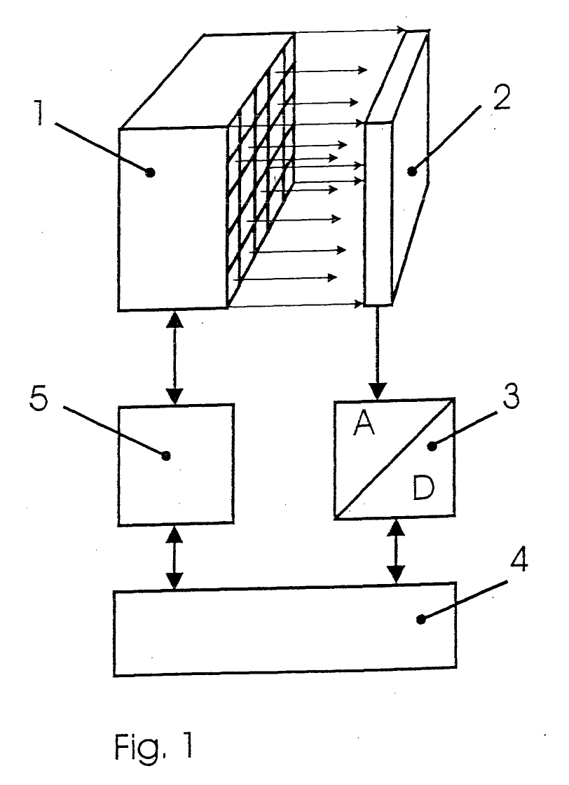

FIG. 1 schematically shows an apparatus for the testing of solar cells which is equipped with a matrix light source;

FIG. 2 schematically shows the actual matrix light source having LEDs and actuation network, reference measuring arrangement, including feedback network, and power supply;

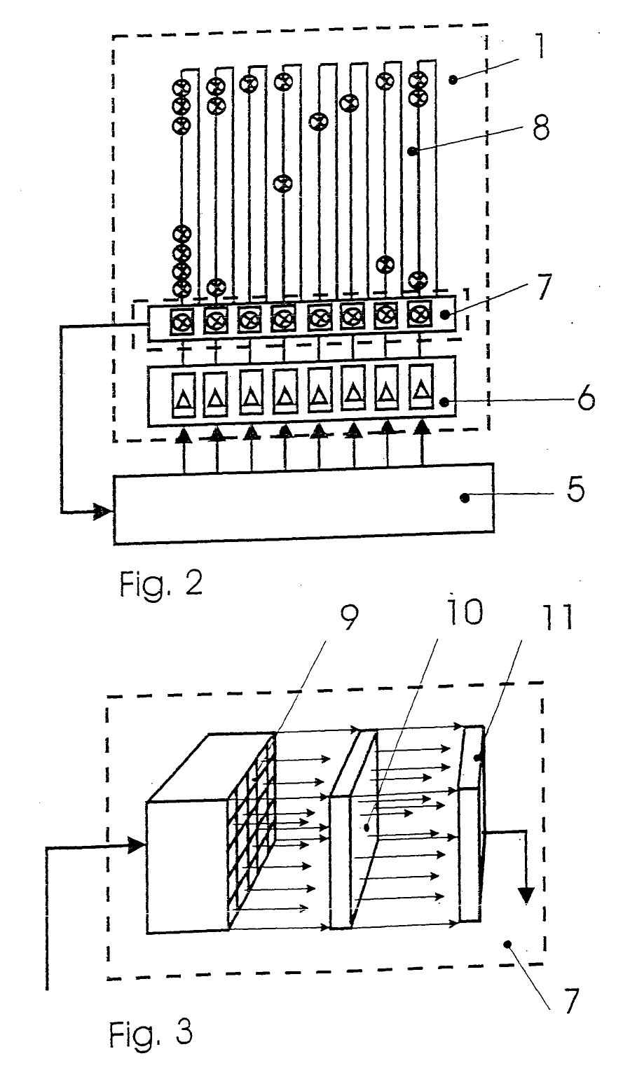

FIG. 3 schematically shows the reference measuring arrangement with reference LEDs, light adaptation filter and evaluation sensor;

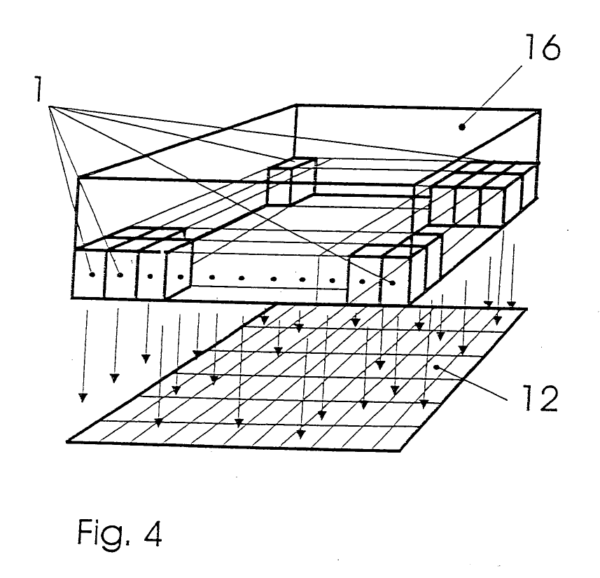

FIG. 4 schematically shows the double-matrix light source, expanded in a modular manner, for test specimens having a larger area, e.g. photovoltaic modules;

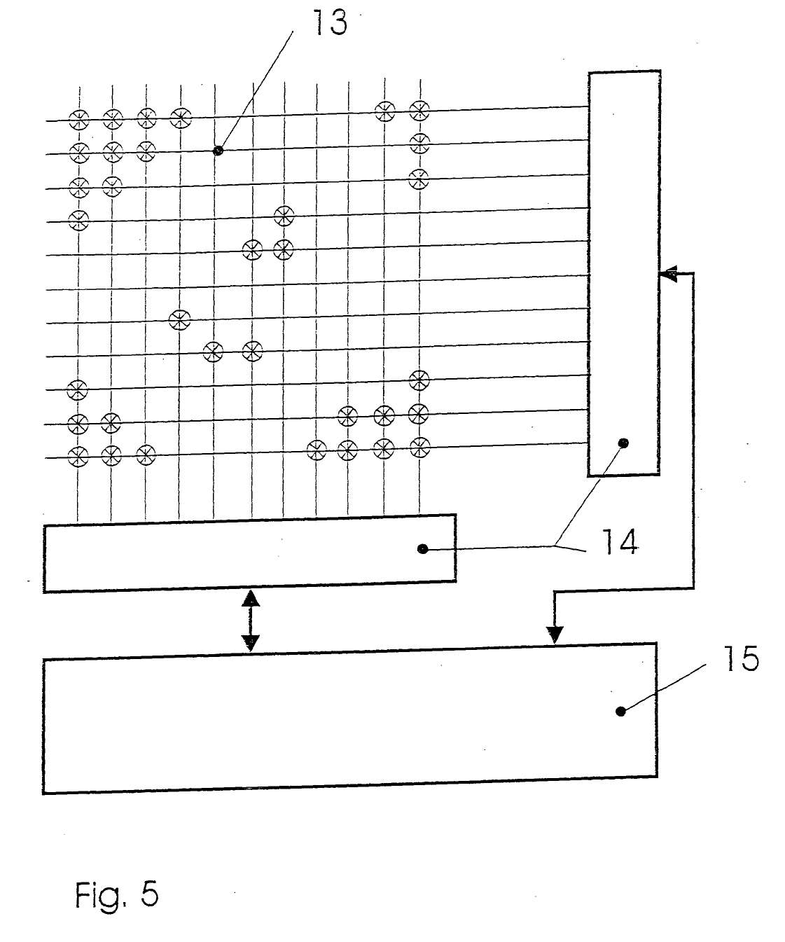

FIG. 5 schematically shows a matrix light source arrangement with x-y actuation for testing the homogeneity of solar cells.

FIG. 1 shows an apparatus for measuring solar cells, comprising a matrix light source 1, consisting of a large number of solid-state light sources which are supplied with energy by a computer-controlled current source 5. The solid-state light sources are dimensioned with regard to their spectral light emission in such a way that their emitted light energy in the optimum spectral sensitivity range of solar cells 2 can be converted into electrical current. The measurement current generated is directly proportional to the radiant energy. The analogue measurement current is converted into a digital measured signal via an analogue/digital converter 3, in order to be further processed in an evaluation unit/test computer 4.

According to the invention, LEDs in the spectral region of 880 nm are used as solid-state light sources because the radiant energy at this wavelength is most readily converted by the silicon solar cells. Here, a calibrated reference cell is first fed in a defined time unit and with a radiant power of the matrix light source 1 increasing in a defined manner, via the controlled diode current of the computer-controlled current source 5. Up to a calibration value of 1000 W/m², the associated generated current or a voltage is recorded via a test shunt. The reference cell has a test temperature of 25° C. (STC).

After this calibration of the measuring apparatus shown in FIG. 1, any desired solar cell or any corresponding radiation sensor of the same cell material can be irradiated and the measured current correlating with the incident radiation can be determined. Deviations of this measured current from that of the reference cell are taken into account via correction factors or calibration curves.

FIG. 2 shows details of the matrix light source 1 disclosed in FIG. 1. In the present embodiment, the individual LEDs are installed in at least 20 parallel strands (columns) and these in turn are installed as a series circuit (lines) of at least 20 LEDs over the area of a matrix light source circuit board 8. The individual LED strands are supplied with a defined current via driver modules 6 from a computer-controlled current source 5. For monitoring and control of the strand currents, the radiation of an LED is output from each strand so that said strand current can be evaluated in a reference light source feedback network 7.

FIG. 3 shows this reference light source feedback network 7 in details according to the invention. The reference LEDs 9 whose radiation is output are likewise in the form of a matrix-like light source in the present embodiment. A solar cell or a light sensor chip 11 is irradiated via an adaptation filter 10. Since the light intensity of the matrix light source 1 can be adjusted via the current of the LEDs, the reference light source feedback network 7 serves as a compensation means for ageing phenomena or temperature deviations of the matrix light source circuit board 8.

FIG. 4 shows the matrix light source 1 already described in FIG. 2, according to the invention in modular extension as a large-area double-matrix light source 16. According to the embodiment, measuring tasks, as described above under FIG. 1, can be carried out here for photovoltaic modules 12 by way of example.

FIG. 5 shows the example of an XY matrix light source 13 with appropriately modified electronic circuit board, the decoder assembly 14 for x lines and y columns and a programmable current source 15. According to the embodiment, the individual current monitoring takes place in the programmable current source. According to the invention, a light pulse of defined amplitude and shape is chosen for testing the homogeneity of solar cells in order as far as possible not to cause any faults in the generation process and to be able to evaluate these in a simple manner.

1. Apparatus for the testing of solar cells, comprising
a defined matrix light source (1) for irradiating the solar cells (2),
a means for actuating the light source with a current regulator and
an evaluation unit (4) for electrical connection to a solar cell (2) to be tested and for measuring the electrical power output by the irradiated solar cell and, if required, for comparison with the power of a calibrated reference cell (11),
characterized in that the matrix light source is composed of solid-state light sources whose radiation emission is substantially monochromatic and is in the preferred spectral sensitivity range of the solar cells (2) to be measured.

2. Apparatus according to claim 1, for the testing of Si solar cells (2), in particular with output of a specific radiant power of 1200 W/m² at 25° C., characterized in that the matrix light source has solid-state light sources which emit radiation having a maximum in the infrared range, preferably at 880 nm.

3. Apparatus according to claim 1, for the testing of CIS or CdTe solar cells (2), in particular with output of a specific radiant power of 1200 W/m² at 25° C., characterized in that the matrix light source has solid-state light sources which emit radiation having a maximum in the red range, preferably at 600 nm or 700 nm.

4. Apparatus according to claim 1, for the testing of solar cells (2) of amorphous silicon, in particular with output of a specific radiant power of 1200 W/m² at 25° C., characterized in that the matrix light source has solid-state light sources which emit radiation having a maximum in the blue or blue-violet range, preferably at 450 nm.

5. Apparatus according to claims 1 or 2-4, characterized in that the matrix light source has at least 400 solid-state light sources for the testing of 10×10 cm solar cells.

6. Apparatus according to at least one of claims 1-5, characterized in that the solid-state light sources are LEDs having lenticular radiation orifices and their matrix-like arrangement at a distance of 4.3 mm+10% forms an approximately homogeneous radiation area.

7. Apparatus according to at least one of claims 1-6, characterized in that the means for actuating the light source is integrated in a computer-controlled evaluation unit (4).

8. Apparatus according to claim 7, characterized in that the means for actuating the light source is a computer-controlled current source (5) having a reference light source feedback network (7).

9. Apparatus according to at least one of claims 1-8, characterized in that the matrix light source (1) is modular and can be extended by addition of modules.

10. Apparatus according to at least one of claims 1-9, characterized in that the matrix light source (13) is in the form of an XY matrix and the currents of the solid-state light sources are individually controllable.

11. Apparatus according to claim 10, referring back to at least one of claims 1 and 5-9, characterized in that the matrix light source (1) comprises groups of solid-state light sources of different spectral light emission, and a desired mixed spectrum can be produced by suitable actuation of the groups.
